(19) United States
(12) Patent Application Publication
(10) Pub. No.: US 2025/0372396 A1
(43) Pub. Date: Dec. 4, 2025

(54) METHOD FOR MANUFACTURING MOS DEVICE

(71) Applicant: INSTITUTE OF MICROELECTRONICS, CHINESE ACADEMY OF SCIENCES, Beijing (CN)

(72) Inventors: Jun LUO, Beijing (CN); Mengjuan KONG; Xianglie SUN, Beijing (CN); Jing XU, Beijing (CN); Junfeng LI, Beijing (CN)

(21) Appl. No.: 18/710,785

(22) PCT Filed: Nov. 23, 2023
(86) PCT No.: PCT/CN2023/133565

§ 371 Date: May 16, 2024

(30) Foreign Application Priority Data
Nov. 25, 2022 (CN) 202211515818.8

(51) Int. Cl. H01L 21/3205; H01L 21/321; H01L 21/3215; H10D 30/01

(52) U.S. Cl. CPC H01L 21/32053; H01L 21/32105; H01L 21/32155; H10D 30/024

(57) ABSTRACT

A method for manufacturing a MOS device, comprising: providing a substrate comprising a gate portion and a source-or-drain portion, where a through hole is formed in a dielectric layer disposed on the substrate and exposes a surface of the source-or-drain portion; doping the source-or-drain portion; amorphizing the doped source-or-drain portion to form an amorphous layer on a surface of the source-or-drain portion; oxidizing the source-or-drain portion to segregate dopants in adjacency of the amorphous layer; removing the oxidized amorphous layer; and forming a metal silicide on the surface of the source-or-drain portion. Contact resistance of a source and/or a drain is significantly reduced.

This application claims the priority to Chinese Patent Application No. 202211515818.8, titled “METHOD FOR MANUFACTURING MOS DEVICE”, filed with the China National Intellectual Property Administration on Nov. 25, 2022, the entire content of which is incorporated herein by reference.

### FIELD

The present disclosure relates to the technical field of semiconductors, and in particular to a method for manufacturing a MOS device.

### BACKGROUND

Among semiconductor devices, those having a metal-oxide-semiconductor (MOS) structure, such as MOS devices and complementary MOS (CMOS) devices, have gained wide application.

Contact resistance of source/drain regions is crucial for improving device performance with miniaturization of the devices, especially when the devices have entered a technical node of 16/14 nm or even lower. How to reduce the contact resistance of source/drain regions has become an urgent technical problem for those skilled in the art.

### SUMMARY

In order to address at least the above issue, a method for manufacturing metal-oxide-semiconductor (MOS) device is provided according to embodiments of the present disclosure. Concentration of activated dopants is increased at surfaces of a source and a drain, and hence contact resistance is reduced for the source and the drain.

A method for manufacturing a MOS device is provided according to an embodiment of the present disclosure. The method comprises: providing a substrate comprising a gate portion and a source-or-drain portion, where a through hole is formed in a dielectric layer disposed on the substrate and exposes a surface of the source-or-drain portion; doping the source-or-drain portion; amorphizing the doped source-or-drain portion to form an amorphous layer on a surface of the source-or-drain portion; oxidizing the source-or-drain portion to segregate dopants in adjacency of the amorphous layer; removing the oxidized amorphous layer; and forming a metal silicide on the surface of the source-or-drain portion.

In an embodiment, doping the source-or-drain portion comprises: doping the source-or-drain portion through ion implantation or in-situ doping.

In an embodiment, amorphizing the doped source-or-drain portion comprises: implanting Ge ions, Si ions, or As ions into the doped source-or-drain portion.

In an embodiment, implanting the Ge ions, the Si ions, or the As ions into the doped source-or-drain portion is performed under an energy ranging from 0.5 keV to 3 keV and a dose ranging from 1×10¹⁴ cm⁻³ to 1×10¹⁶ cm⁻³.

In an embodiment, a thickness of the amorphous layer ranges from 6 nm to 9 nm.

In an embodiment, oxidizing the source-or-drain portion is performed under temperature ranging from 300° C. to 600° C.

In an embodiment, the method further comprises: performing, before amorphizing the source-or-drain portion, first thermal treatment on the source-or-drain portion to activate dopant; or performing, after oxidizing the source-or-drain portion, first thermal treatment on the source-or-drain portion to activate dopant.

In an embodiment, forming the metal silicide on the surface of the source-or-drain portion comprises: depositing a metal layer which covers a bottom and a sidewall of the through hole and covers a surface of the dielectric layer; and performing second thermal treatment on the source-or-drain portion to form the metal silicide through reaction between the metal layer and a material at the surface of the source-or-drain portion.

In an embodiment, a material of the metal layer is Ti, TiN, or a combination of Ti and TiN.

In an embodiment, the second thermal treatment on the source-or-drain portion is performed through rapid thermal annealing or laser annealing, under a temperature ranging 400° C. to 600° C., and for a period ranging from 10 s to 60 s.

Herein the method for manufacturing the MOS device is provided. After a source and/or a drain are doped, the surface of the substrate is amorphized and then oxidized. The oxidation is capable to introduce segregation of the dopants at the surface of the substrate. Thereby, concentration of activated dopants is increased at a surface of the source and/or the drain, and thus contact resistance of the source and/or the drain is reduced. Since the surface is amorphized before the oxidation, the amorphous layer formed on the surface facilitates more dopants concentrating toward the surface of the substrate in the segregation during the oxidation. Moreover, herein the concentration of the dopants at the surface of the source and/or the drain is effectively increased without increasing a junction depth of the source and/or the drain. Processing is simple and compatible with complementary MOS (CMOS) techniques.

### BRIEF DESCRIPTION OF THE DRAWINGS

FIG. 1 is a flowchart of a method for manufacturing a MOS device according to an embodiment of the present disclosure.

FIGS. 2 to 7 are schematic structural diagrams of a cross section of structures in a process of the method for manufacturing a MOS device according to an embodiment of the present disclosure.

### DETAILED DESCRIPTION OF EMBODIMENTS

Hereinafter embodiments of the present disclosure will be described clearly and completely in conjunction with the drawings, in order to clarify objectives, technical solutions, and advantages of the present disclosure. The description is merely exemplary and is not intended for limiting a scope of the present disclosure. All other embodiments capable to be obtained by those skilled in the art on a basis of the embodiments without any creative effort shall fall within the protection scope of the present disclosure. Hereinafter description concerning well-known structures and techniques is omitted in order to avoid confusion on concepts of the present disclosure.

Schematic diagrams of various structures in embodiments of the present disclosure are depicted in the drawings. The drawings are not drawn to scale. Some details may be enlarged and some details may be omitted for the sake of clarity. Shapes, relative sizes, and positional relationship, of various regions and layers as depicted in the drawings are merely exemplary, and they may deviate from practice due to tolerance or technical restrictions in manufacture. Those skilled in the art may utilize a region or a layer different in a shape, a size, or a relative position based on an actual requirement.

Herein when a layer/element is described to be “on” another layer/element, the layer/element may be directly on the other layer/element, or there may be an intermediate layer/element between the two. In addition, when the layer/element is “above” another layer/element in one orientation, the layer/element may be “below” the other layer/element when the orientation is reverted.

Hereinafter some embodiments of the present disclosure are described in detail in conjunction with the drawings. Embodiments and features described hereinafter may be combined with each other as long as there is no conflict.

Theoretically, contact resistance can be reduced through increasing a contact area and reducing contact resistivity. An important manner of reducing the contact resistivity is increasing concentration of activated dopants at a surface of a source and/or a drain. A reason lies in that an increase in the concentration of activated dopants at such surface is capable to decrease a width of the Schottky barrier, and hence probability of carrier tunneling is significantly improved. An objective of a method according to embodiments of the preset disclosure is increasing the concentration of activated dopants.

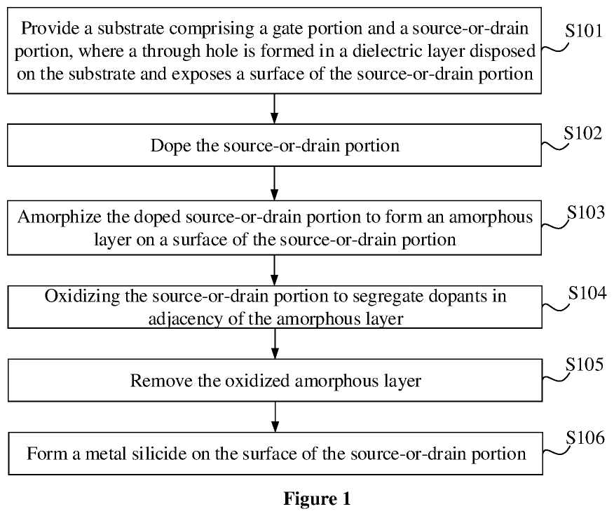

A method for manufacturing a metal-on-semiconductor (MOS) device is provided according to an embodiment of the present disclosure. Reference is made to FIG. 1. The method comprises steps S101 to S106.

In step S101, a substrate is provided, where the substrate comprises a gate portion and a source-or-drain portion, and a through hole is formed in a dielectric layer disposed on the substrate and exposes a surface of the source-or-drain portion.

In step S102, the source-or-drain portion is doped.

In step S103, the doped source-or-drain portion is amorphized to form an amorphous layer on a surface of the source-or-drain portion.

In step S104, the source-or-drain portion is oxidized to segregate dopants in adjacency of the amorphous layer.

In step S105, the oxidized amorphous layer is removed.

In step S106, a metal silicide is formed on the surface of the source-or-drain portion.

The foregoing method is applicable to both three-dimensional (3D) fin-field-effect-transistor (FinFET) devices and planar MOS devices.

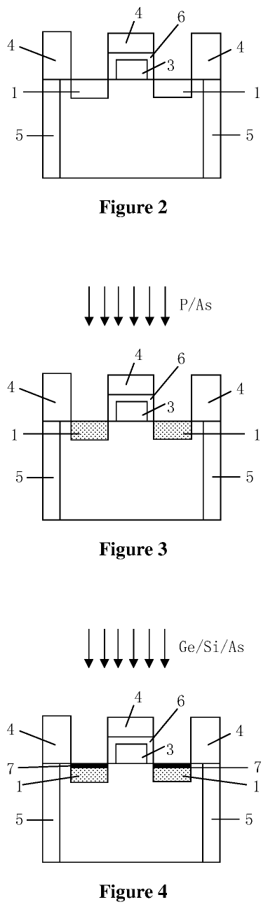

Hereinafter the steps of the foregoing method are described in details. FIGS. 2 to 7 show cross-sectional views of structures in steps of a method according to an embodiment of the present disclosure.

Reference is made to FIG. 2. In step S101, the substrate is provided. A gate portion 3 and source-or-drain portion(s) 1 are provided in the substrate. The through hole is formed in the dielectric layer 4 disposed on the substrate, and the through hole exposes the surface of the source-or-drain portion(s) 1. A material of the substrate may be a semiconductor material, such as Si, Ge, or SiGe. Herein a Si substrate is taken as an example. Shallow trench isolation 5 may be further provided on the substrate. The gate portion 3 may be partially surrounded by a spacer layer 6. In such case, the substrate is a semi-finished substrate on which the source-or-drain portion 1, the gate portion 3, the dielectric layer 4, and the shallow trench isolation 5 have been prepared. A process of fabricating the substrate may refer to conventional technology and is not limited herein.

Reference is made to FIG. 3. In step S102, the source-or-drain portion 1 is doped. The source-or-drain portion 1 may be doped with n-type dopants (such as nitrogen, phosphorus, or arsenic) in a case that the MOS device is an n-channel MOS (NMOS) device, and may be doped with p-type dopants (such as boron, gallium, or indium) in a case that the MOS device is a p-channel MOS (PMOS) device. The source and/or the drain may be through ion implantation or in-situ doping. As an example, ions of p-type dopants is implanted, where energy of the ions ranges from 0.5 keV to 3 keV, and a dose of the ions ranges from 1×10¹⁵ cm⁻³ and 1×10¹⁶ cm⁻³.

Reference is made to FIG. 4. In step S103, the doped source-or-drain portion 1 is amorphized to form the amorphous layer 7 on the surface of the source-or-drain portion. In an embodiment, the amorphization is performed through implanting Ge ions, Si ions, or As ions into the doped source-or-drain portion 1. Conditions for implanting the Ge ions, the Si ions, and the As ions may be identical. In an embodiment, the conditions may be that enery of the ions ranges from 0.5 keV to 3 keV, and a dose of the ions ranges from 1×10¹⁴ cm⁻³ and 1×10¹⁶ cm⁻³.

Generally, a thickness of the amorphous layer 7 may range from 6 nm to 9 nm.

Reference is made to FIG. 5. In step S104, the source-or-drain portion 1 is oxidized to segregate dopants in adjacency of the amorphous layer 7. In such step, the amorphous layer 7 is oxidized and converted into an oxidized amorphous layer 7′. The oxidation introduces segregation of the dopants at the surface of the substrate (that is, a SiO₂/Si interface where the silicon substrate is taken as an example). The amorphous layer 7 can facilitate more dopants concentrating at the surface of the substrate in the segregation during the oxidation. The temperature of the oxidation process may range from 300° C. to 600° C. Herein in-situ steam generation (ISSG) oxidation under 600° C. is taken as an example.

First thermal treatment may be performed on the source-or-drain portion 1 before amorphizing the source-or-drain portion 1. Alternatively, first thermal treatment may be performed on the source-or-drain portion 1 after oxidizing the source-or-drain portion 1. Thereby, the dopants can be activated. In an embodiment, the first thermal treatment is performed through peak annealing under a temperature of 1050° C. for a period of 60 s.

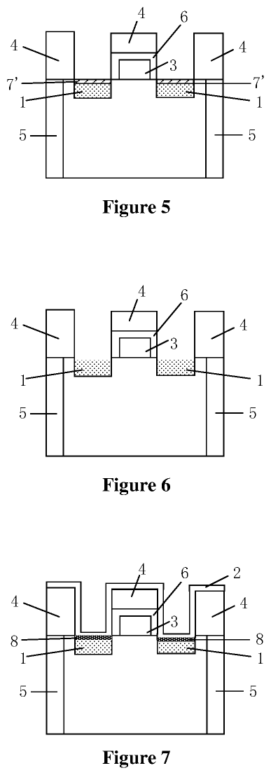

In step S105, the oxidized amorphous layer 7′ is removed. The removal may be implemented through wet etching. FIG. 6 shows a schematic diagram of a structure having the amorphous layer 7′. A material of the oxidized amorphous layer 7′ may be doped SiO₂, and the etchant may be a mixture of HF and water (a ratio of which is 1:100).

Reference is made to FIG. 7. In step S106, the metal silicide 8 is formed on the surface of the source-or-drain portion 1. In an embodiment, such step comprises following sub-steps. First, a metal layer 2, which covers a bottom and a sidewall of the through hole and covers a surface of the dielectric layer 4 is deposited. A material of the metal layer 2 may be Ti, TiN, or a combination of Ti and TiN, or may be another metal for forming a silicide, such as Ni and NiPt. Ti/TiN is widely used in 3D FinFET techniques, where a thickness of Ti ranges from 5 nm to 10 nm and a thickness of TiN ranges from 5 nm to 10 nm. Then, second thermal treatment is performed on the source-or-drain portion 1, so that the metal layer 2 reacts with a material at the surface of the source-or-drain portion 1 to form the metal silicide. In an embodiment, the second thermal treatment on the source-or-drain portion is implemented through rapid thermal annealing or laser annealing, under a temperature ranging from 400° C. to 600° C., and for a period ranging from 10 s to 60 s.

Herein the method for manufacturing the MOS device is provided. After a source and/or a drain are doped, the surface of the substrate is amorphized and then oxidized. The oxidation is capable to introduce segregation of the dopants at the surface of the substrate. Thereby, concentration of activated dopants is increased at a surface of the source and/or the drain, and thus contact resistance of the source and/or the drain is reduced. Since the surface is amorphized before the oxidation, the amorphous layer formed on the surface facilitates more dopants concentrating toward the surface of the substrate in the segregation during the oxidation. Moreover, herein the concentration of the dopants at the surface of the source and/or the drain is effectively increased without increasing a junction depth of the source and/or the drain. Processing is simple and compatible with CMOS techniques.

In addition, there may be some subsequent processing after the metal silicide is formed. For example, the metal layer on the surface is removed, a through hole is filled with metal to connect the source-or-drain region electrically to outside, or the like. Such processing may be conventional in the field and is not described herein.

Hereinabove technical details such as a pattern of each layer and etching on the layers may be omitted. Those skilled in the art have various technical means for forming a layer, a region, or the like, of a desired shape. Those skilled in the art may derive a means which is not exactly identical to aforementioned one for fabricating the same structure. In addition, embodiments that are separately described do not indicate that their features cannot be combined and applied to achieve an advantage.

Described above are only embodiments of the present disclosure, and a protection scope of the present disclosure is not limited to these embodiments. Any modification or replacement that can be easily conceived by those skilled in the art within the technical scope disclosed herein shall fall within a protection scope of the present disclosure. Therefore, the protection scope of the present disclosure is subject to a scope of the claims.

1. A method for manufacturing a MOS device, comprising:
providing a substrate comprising a gate portion and a source-or-drain portion, wherein a through hole is formed in a dielectric layer disposed on the substrate and exposes a surface of the source-or-drain portion;
doping the source-or-drain portion with dopants;
amorphizing the doped source-or-drain portion to form an amorphous layer on a surface of the source-or-drain portion;
oxidizing the amorphous layer on the surface of the source-or-drain portion to segregate the dopants in adjacency of the amorphous layer;
removing the oxidized amorphous layer; and
forming a metal silicide on the surface of the source-or-drain portion after removing the oxidized amorphous layer.

2. The method according to claim 1, wherein doping the source-or-drain portion comprises:
doping the source-or-drain portion through ion implantation or in-situ doping.

3. The method according to claim 1, wherein amorphizing the doped source-or-drain portion comprises:
implanting Ge ions, Si ions, or As ions into the doped source-or-drain portion.

4. The method according to claim 3, wherein when implanting the Ge ions, the Si ions, or the As ions into the doped source-or-drain portion, an energy of the Ge ions, the Si ions, or the As ions ranges from 0.5 keV to 3 keV and a dose of the Ge ions, the Si ions, or the As ions ranges from 1×10¹⁴ cm⁻³ to 1×10¹⁶ cm⁻³.

5. The method according to claim 1, wherein a thickness of the amorphous layer ranges from 6 nm to 9 nm.

6. The method according to claim 1, wherein oxidizing the amorphous layer on the surface of the source-or-drain portion is performed under temperature ranging from 300° C. to 600° C.

7. The method according to claim 1, further comprising:
performing, before amorphizing the source-or-drain portion, first thermal treatment on the source-or-drain portion to activate dopant; or
performing, after oxidizing the amorphous layer on the surface of the source-or-drain portion, first thermal treatment on the source-or-drain portion to activate dopant.

8. The method according to claim 1, wherein forming the metal silicide on the surface of the source-or-drain portion comprises:
depositing a metal layer which covers a bottom and a sidewall of the through hole and covers a surface of the dielectric layer; and
performing second thermal treatment on the source-or-drain portion to form the metal silicide through reaction between the metal layer and a material at the surface of the source-or-drain portion.

9. The method according to claim 8, wherein a material of the metal layer is Ti, TiN, or a combination of Ti and TiN.

10. The method according to claim 8, wherein the second thermal treatment on the source-or-drain portion is performed through rapid thermal annealing or laser annealing, under a temperature ranging 400° C. to 600° C., and for a period ranging from 10 s to 60 s.
